(19) United States
(12) Patent Application Publication
(10) Pub. No.: US 2013/0092956 A1
(43) Pub. Date: Apr. 18, 2013

(54) SILICON CARBIDE SUBSTRATE, SILICON CARBIDE SEMICONDUCTOR DEVICE, METHOD FOR MANUFACTURING SILICON CARBIDE SUBSTRATE, AND METHOD FOR MANUFACTURING SILICON CARBIDE SEMICONDUCTOR DEVICE

(71) Applicant: Sumitomo Electric Industries, Ltd., Osaka (JP)

(72) Inventors: Keiji ISHIBASHI, Itami-shi (JP); Tsutomu HORI, Itami-shi (JP); Shunsaku UETA, Itami-shi (JP); Yu SAITOH, Osaka (JP); Kosuke UCHIDA, Itami-shi (JP)

(73) Assignee: SUMITOMO ELECTRIC INDUSTRIES, LTD., Osaka (JP)

(21) Appl. No.: 13/647,648

(22) Filed: Oct. 9, 2012

Related U.S. Application Data
(60) Provisional application No. 61/546,729, filed on Oct. 13, 2011.

(30) Foreign Application Priority Data
Oct. 13, 2011 (JP) 2011-225595

(51) Int. Cl. H01L 29/24; H01L 21/20

(52) U.S. Cl. 257/77; 438/478; 257/E29.104; 257/E21.09

(57) ABSTRACT

Single crystal substrates are made of silicon carbide, and each have a first front-side surface and a first backside surface opposite to each other. A support substrate has a second front-side surface and a second backside surface opposite to each other. A connection layer has silicon carbide as a main component, and lies between the single crystal substrates and the support substrate for connecting each of the first backside surfaces and the second front-side surface such that each of the first backside surfaces faces the second front-side surface.

### BACKGROUND OF THE INVENTION

1. Field of the Invention

The present invention relates to a silicon carbide substrate, a silicon carbide semiconductor device, a method for manufacturing a silicon carbide substrate, and a method for manufacturing a silicon carbide semiconductor device.

2. Description of the Background Art

In recent years, a silicon carbide (SiC) crystal has begun to be adopted as a semiconductor substrate used to manufacture a semiconductor device. SiC has a bandgap larger than that of silicon (Si), which has been more commonly used. Hence, the semiconductor device using SiC has advantages such as high breakdown voltage, low ON resistance, and less deterioration in characteristics under a high temperature environment.

In order to efficiently manufacture a semiconductor device using a semiconductor substrate, the semiconductor substrate must be of a certain size or larger. However, it is difficult to form a large-diameter SiC single crystal substrate while maintaining high quality, and its industrially available size is about 100 mm (4 inches) at the largest. To deal with this issue, methods for manufacturing a large-diameter silicon carbide substrate by fixing a plurality of SiC single crystal substrates on a front-side surface of one large-diameter support substrate and integrating them are currently under consideration.

For example, according to International Publication No. 2010/131569, each of SiC single crystal substrates is arranged to face a SiC wafer, and thereafter a temperature gradient which allows the SiC wafer to have a relatively higher temperature is formed. Thereby, SiC sublimed from the SiC wafer is recrystallized as a support substrate extending over a plurality of SiC single crystal substrates, and the plurality of SiC single crystal substrates are integrated. Namely, a large-diameter silicon carbide substrate is obtained. In addition, Japanese Patent Laying-Open No. 2011-071196 describes a method for obtaining a large-diameter silicon carbide substrate by connecting a plurality of SiC single crystal substrates using a connection layer made of silicon (Si).

However, according to the method described in International Publication No. 2010/131569, since the SiC single crystal substrates are exposed to a high-temperature environment at about the sublimation temperature of SiC, dislocation defects tend to be generated in the SiC single crystal substrates. Further, during formation of the support substrate using sublimation and recrystallization of SiC, voids may be generated in the support substrate, move to a backside surface of the support substrate, and form irregularities in the backside surface of the support substrate. The irregularities may cause a reduction in the strength of the silicon carbide substrate.

In addition, according to the method described in Japanese Patent Laying-Open No. 2011-071196, since there is a large difference between the thermal expansion coefficient of the SiC single crystal substrates and the thermal expansion coefficient of the connection layer made of Si, the SiC single crystal substrates may be delaminated from the connection layer. Further, since Si has a melting point lower than that of SiC, when the silicon carbide substrate obtained by this method is used to manufacture a semiconductor device, Si may be melted in high-temperature treatment during a manufacturing process, and thereby the connected SiC single crystal substrates may be separated from each other.

Thus, the silicon carbide substrates formed by the conventional methods described above may not be optimal for manufacturing a silicon carbide semiconductor device.

### SUMMARY OF THE INVENTION

The present invention has been made in view of the above circumstances, and one object of the present invention is to provide a silicon carbide substrate suitable for manufacturing a silicon carbide semiconductor device, and a method for manufacturing the same. In addition, another object of the present invention is to provide a silicon carbide semiconductor device using the silicon carbide substrate described above, and a method for manufacturing the same.

A silicon carbide substrate in accordance with the present invention includes single crystal substrates, a support substrate, and a connection layer. The single crystal substrates are made of silicon carbide, and each have a first front-side surface and a first backside surface opposite to each other. The support substrate has a second front-side surface and a second backside surface opposite to each other. The connection layer has silicon carbide as a main component, and lies between the plurality of single crystal substrates and the support substrate for connecting each of the first backside surfaces and the second front-side surface such that each of the first backside surfaces faces the second front-side surface.

According to the silicon carbide substrate, since the connection layer has silicon carbide as a main component, the thermal expansion coefficient of the single crystal substrates is close to the thermal expansion coefficient of the connection layer. Thereby, adhesion strength between the single crystal substrates and the connection layer is maintained even under an environment having temperature changes. Therefore, the silicon carbide substrate is suitable for manufacturing a silicon carbide semiconductor device.

Preferably, in the silicon carbide substrate, the connection layer has a porosity of not less than 3% and not more than 65%. When the connection layer has a porosity of not more than 65%, adhesion strength is enhanced. When the connection layer has a porosity of not less than 3%, a Young's modulus of the connection layer is reduced, and thus the connection layer has an enhanced function as a stress relaxation layer between the single crystal substrates and the support substrate.

Preferably, in the silicon carbide substrate, the support substrate is made of silicon carbide. Thereby, the thermal expansion coefficient of the support substrate is also close to the thermal expansion coefficient of the connection layer. Thus, adhesion strength between the connection layer and the support substrate is enhanced.

Preferably, in the silicon carbide substrate, the connection layer has a crystallization degree lower than that of the support substrate. Thereby, the Young's modulus of the connection layer is reduced, and thus the connection layer has an enhanced function as a stress relaxation layer between the single crystal substrates and the support substrate.

Preferably, in the silicon carbide substrate, the connection layer has at least one of polycrystalline silicon carbide and amorphous silicon carbide as a main component.

Preferably, in the silicon carbide substrate, a ratio A/B between a number A of carbon atoms and a number B of silicon atoms in the connection layer is not less than 1 and not more than 2. Thereby, the thermal expansion coefficient of the connection layer is close to the thermal expansion coefficient of the single crystal substrates, when compared with a case where ratio A/B is more than 2.

Preferably, the silicon carbide substrate has a diameter of not less than 110 mm. Thereby, a large-diameter silicon carbide substrate, which has been industrially difficult to be obtained, can be provided.

Preferably, the silicon carbide substrate has a warpage of not more than 30 μm. Thereby, a silicon carbide substrate with a sufficiently small warpage can be provided, and thus the silicon carbide substrate can be further suitably utilized as a semiconductor substrate for a semiconductor device.

Preferably, in the silicon carbide substrate, each of the plurality of single crystal substrates has a hexagonal crystal structure, and the first front-side surface has a plane orientation which is off from a {0001} plane by not less than 0.1° and not more than 10°. In this case, an epitaxial layer can be satisfactorily grown on the first front-side surfaces of the single crystal substrates, and thus the silicon carbide substrate can be more suitably utilized as a semiconductor substrate for a silicon carbide semiconductor device.

Preferably, in the silicon carbide substrate, each of the plurality of single crystal substrates has a hexagonal crystal structure, and the first front-side surface has a plane orientation which is off from a {03-38} plane by not more than 4°. Thereby, channel mobility in each first front-side surface can be improved, and thus the silicon carbide substrate can be more suitably utilized as a semiconductor substrate for a silicon carbide semiconductor device.

A silicon carbide semiconductor device in accordance with the present invention includes a single crystal substrate, a support substrate, a connection layer, an epitaxial layer, and an electrode. The single crystal substrate is made of silicon carbide, and has a first front-side surface and a first backside surface opposite to each other. The support substrate has a second front-side surface and a second backside surface opposite to each other. The connection layer has silicon carbide as a main component, and lies between the single crystal substrate and the support substrate for connecting the first backside surface and the second front-side surface such that the first backside surface faces the second front-side surface. The epitaxial layer is provided on the first front-side surface of the single crystal substrate, and is made of silicon carbide. The electrode is provided on the epitaxial layer.

According to the silicon carbide semiconductor device, since the connection layer has silicon carbide as a main component, the thermal expansion coefficient of the single crystal substrate is close to the thermal expansion coefficient of the connection layer. Thereby, adhesion strength between the single crystal substrate and the connection layer is maintained even under an environment having temperature changes.

A method for manufacturing a silicon carbide substrate in accordance with the present invention includes the steps of: preparing a plurality of single crystal substrates and a support substrate, the plurality of single crystal substrates being made of silicon carbide and each having a first front-side surface and a first backside surface opposite to each other, the support substrate having a second front-side surface and a second backside surface opposite to each other; arranging each of the plurality of single crystal substrates on the support substrate with a fluid layer containing polycarbosilane interposed therebetween, such that each of the first backside surfaces of the plurality of single crystal substrates faces the second front-side surface of the support substrate; and forming a connection layer having silicon carbide as a main component by converting polycarbosilane.

According to the method for manufacturing a silicon carbide substrate, the plurality of single crystal substrates can be attached to (integrated with) the support substrate, using the connection layer having silicon carbide as a main component that is formed by converting polycarbosilane. Since the single crystal substrates are made of silicon carbide and the connection layer has silicon carbide as a main component in the silicon carbide substrate, the thermal expansion coefficient of the single crystal substrates is close to the thermal expansion coefficient of the connection layer. Thereby, adhesion strength between the single crystal substrates and the connection layer is maintained even under an environment having temperature changes.

Preferably, in the method for manufacturing a silicon carbide substrate, the fluid layer contains dispersed silicon. This can avoid an excessive increase in the porosity of the connection layer formed from the fluid layer.

Preferably, in the method for manufacturing a silicon carbide substrate, the step of forming the connection layer includes the step of heating the fluid layer at not less than 1000° C. and not more than 2000° C. By heating the fluid layer at not more than 2000° C., an increase in dislocation density in the single crystal substrates can be suppressed. By heating the fluid layer at not less than 1000° C., polycarbosilane can be more efficiently converted into the connection layer having silicon carbide as a main component.

Preferably, in the method for manufacturing a silicon carbide substrate, the fluid layer contains a filler made of silicon carbide. This can suppress contraction when polycarbosilane is converted into the connection layer. Thus, adhesion strength of the connection layer with respect to each of the single crystal substrates and the support substrate can be maintained high.

Preferably, in the method for manufacturing a silicon carbide substrate, after the step of forming the connection layer, the silicon carbide substrate has a warpage of not more than 50 μm. Thereby, when the silicon carbide substrate is used to manufacture a silicon carbide semiconductor device, processing cost and processing time for planarizing a front-side surface of the silicon carbide substrate can be reduced.

A method for manufacturing a silicon carbide semiconductor device in accordance with the present invention includes the steps of: preparing a silicon carbide substrate including a single crystal substrate, a support substrate, and a connection layer, the single crystal substrate being made of silicon carbide and having a first front-side surface and a first backside surface opposite to each other, the support substrate having a second front-side surface and a second backside surface opposite to each other, the connection layer having silicon carbide as a main component and lying between the single crystal substrate and the support substrate for connecting the first backside surface and the second front-side surface such that the first backside surface faces the second front-side surface; forming an epitaxial layer on the single crystal substrate; and forming an electrode on the epitaxial layer.

According to the method for manufacturing a silicon carbide semiconductor device, since the connection layer has silicon carbide as a main component, the thermal expansion coefficient of the connection layer is close to the thermal expansion coefficient of the single crystal substrate made of silicon carbide. Thereby, adhesion strength between the single crystal substrate and the connection layer is maintained even under an environment having temperature changes in the manufacturing of the silicon carbide semiconductor device. This improves yield of the silicon carbide semiconductor devices.

As described above, the present invention can provide a silicon carbide substrate suitable for manufacturing a silicon carbide semiconductor device, a method for manufacturing the silicon carbide substrate, a silicon carbide semiconductor device using the silicon carbide substrate, and a method for manufacturing the silicon carbide semiconductor device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a structure of a silicon carbide substrate in accordance with Embodiment 1 of the present invention.

FIG. 2 is a schematic cross sectional view taken along a line II-II in FIG. 1.

FIG. 3 is a schematic flowchart of a method for manufacturing the silicon carbide substrate in accordance with Embodiment 1.

FIG. 4 is a cross sectional view schematically showing one step of the method for manufacturing the silicon carbide substrate in accordance with Embodiment 1.

FIG. 5 is a cross sectional view schematically showing another step of the method for manufacturing the silicon carbide substrate in accordance with Embodiment 1.

FIG. 6 is a cross sectional view schematically showing a structure of a silicon carbide substrate in accordance with Embodiment 2 of the present invention.

FIG. 7 is a partial cross sectional view schematically showing a configuration of a semiconductor device in accordance with Embodiment 3 of the present invention.

FIG. 8 is a schematic flowchart of a method for manufacturing the semiconductor device in accordance with Embodiment 3.

FIG. 9 is a cross sectional view schematically showing one step of the method for manufacturing the semiconductor device in accordance with Embodiment 3.

FIG. 10 is a cross sectional view schematically showing another step of the method for manufacturing the semiconductor device in accordance with Embodiment 3.

FIG. 11 is a cross sectional view schematically showing still another step of the method for manufacturing the semiconductor device in accordance with Embodiment 3.

FIG. 12 is a cross sectional view schematically showing still another step of the method for manufacturing the semiconductor device in accordance with Embodiment 3.

### DESCRIPTION OF THE PREFERRED EMBODIMENTS

Hereinafter, embodiments of the present invention will be described with reference to the drawings. It is noted that, in the below-mentioned drawings, identical or corresponding parts will be designated by the same reference numerals, and the description thereof will not be repeated. Further, in the present specification, an individual plane is represented by ( ) a group plane is represented by { }, and a group orientation is represented by < >. In addition, a negative index is supposed to be crystallographically indicated by putting “-” (bar) above a numeral, but is indicated by putting the negative sign before the numeral in the present specification.

### Embodiment 1

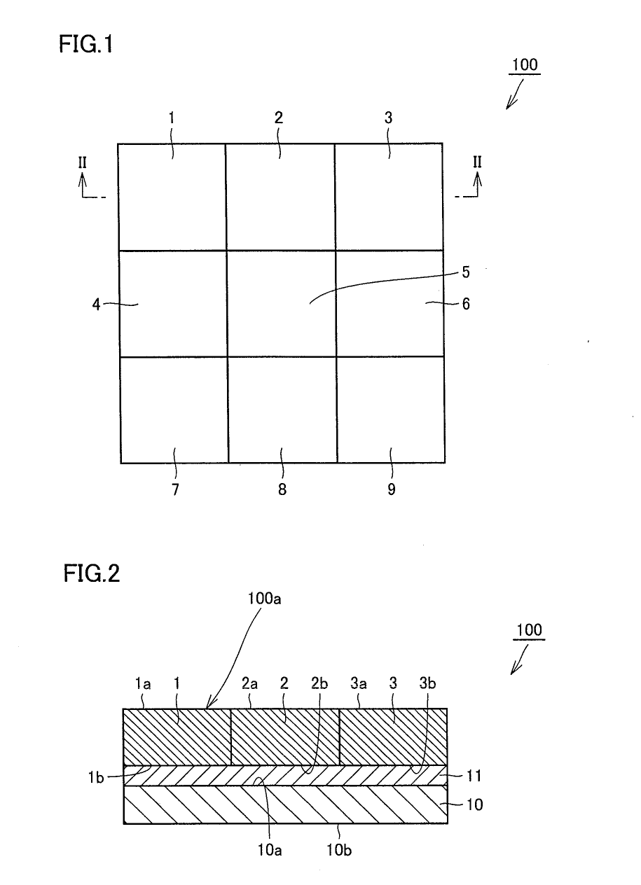

Referring to FIGS. 1 and 2, a silicon carbide substrate 100 in accordance with the present embodiment has single crystal substrates 1 to 9, a support substrate 10, and a connection layer 11.

Each of single crystal substrates 1 to 9 has a first front-side surface (an exposed surface in FIGS. 1 and 2) and a first backside surface (a surface in contact with connection layer 11 in FIG. 2) opposite to each other. For example, referring to FIG. 2, single crystal substrate 1 has a first front-side surface 1a and a first backside surface 1b opposite to each other, single crystal substrate 2 has a first front-side surface 2a and a first backside surface 2b opposite to each other, and single crystal substrate 3 has a first front-side surface 3a and a first backside surface 3b opposite to each other. Each of single crystal substrates 1 to 9 is made of a single crystal of silicon carbide. Hereinafter, for simplicity of description, only at least one of single crystal substrates 1 to 9 (FIG. 1) may be referred to. It is noted, however, each of single crystal substrates 1 to 9 is treated in the same manner.

Preferably, in the present embodiment, the crystal structure of each of single crystal substrates 1 to 9 is a hexagonal crystal structure, and each first front-side surface has a plane orientation which is off from a {0001} plane by not less than 0.1° and not more than 10°. Thereby, an epitaxial layer can be satisfactorily grown on a surface 100a formed of the first front-side surfaces of single crystal substrates 1 to 9, and thus silicon carbide substrate 100 can be suitably utilized as a semiconductor substrate for a semiconductor device.

Further, the first front-side surfaces of single crystal substrates 1 to 9 may each have a plane orientation which is off from a {03-38} plane by not more than 4°. Thereby, channel mobility in each first front-side surface can be improved, and thus silicon carbide substrate 100 can be more suitably utilized as a semiconductor substrate for a semiconductor device. In addition, each first front-side surface may have a plane orientation which is off from a {01-12} plane or a {01-11} plane by not more than 4°.

Support substrate 10 has a second backside surface 10b (an exposed surface in FIG. 2) and a second front-side surface 10a (a surface in contact with connection layer 11 in FIG. 2) opposite to each other. Support substrate 10 is larger than each of single crystal substrates 1 to 9. In FIG. 2, second front-side surface 10a of support substrate 10 has an area substantially identical to that of surface 100a formed of the first front-side surfaces of single crystal substrates 1 to 9.

Support substrate 10 is preferably made of a material capable of withstanding a temperature of 1000° C. or more, and is made of, for example, silicon carbide, carbon, ceramics, or a high-melting-point metal. As the high-melting-point metal, for example, molybdenum, tantalum, tungsten, niobium, iridium, ruthenium, zirconium, or the like can be used. In particular, when support substrate 10 is made of silicon carbide, support substrate 10 can have physical properties closer to those of single crystal substrates 1 to 9.

Connection layer 11 lies between each of single crystal substrates 1 to 9 and support substrate 10. More specifically, referring to FIG. 2, connection layer 11 connects each of first backside surfaces 1b to 3b of single crystal substrates 1 to 3 and second front-side surface 10a of the support substrate such that each of first backside surfaces 1b to 3b faces second front-side surface 10a.

In the present embodiment, connection layer 11 has silicon carbide as a main component. More specifically, connection layer 11 is made of a compound having silicon carbide as a main component that is formed by converting polycarbosilane, which is a polymer having a silicon-carbon bond (hereinafter also referred to as a “Si—C bond”) in a main chain. Here, the main component refers to a component having the number of atoms that accounts for not less than 50% of the number of atoms constituting a compound. That is, not less than 50% of the atoms in connection layer 11 form silicon carbide having Si—C bonds.

Therefore, since single crystal substrates 1 to 9 are made of silicon carbide and connection layer 11 has silicon carbide as a main component in silicon carbide substrate 100, the thermal expansion coefficient of single crystal substrates 1 to 9 is close to the thermal expansion coefficient of connection layer 11. This enhances adhesion strength between single crystal substrates 1 to 9 and connection layer 11, and thus suppresses delamination of single crystal substrates 1 to 9 from connection layer 11. Accordingly, silicon carbide substrate 100 can have a high strength.

Preferably, in silicon carbide substrate 100, a ratio A/B between a number A of carbon atoms and a number B of silicon atoms in connection layer 11 is not less than 1 and not more than 2. Thereby, the thermal expansion coefficient of connection layer 11 is closer to the thermal expansion coefficient of single crystal substrates 1 to 9, when compared with a case where ratio A/B is more than 2. Thus, silicon carbide substrate 100 can have a higher strength. If ratio A/B is less than 1, excess silicon exits in connection layer 11, and the excess silicon is melted during heat treatment at a high temperature due to the low melting point of silicon, which may cause a reduction in the strength of silicon carbide substrate 100. More preferably, ratio A/B is not less than 1 and not more than 1.5.

In particular, connection layer 11 is preferably made of carbon and silicon only. It has been found that, in this case, silicon carbide substrate 100 can have a further higher strength. This is considered to be because the thermal expansion coefficient of connection layer 11 is further closer to the thermal expansion coefficient of single crystal substrates 1 to 9.

Connection layer 11 has a porosity of preferably not more than 65%, more preferably not more than 50%, and further preferably not more than 40%. Since the porosity is not too high, adhesion strength is enhanced. In addition, the porosity is preferably not less than 3%, more preferably not less than 5%, and further preferably not less than 10%. Since the porosity is not too low, a Young's modulus of connection layer 11 is sufficiently reduced. Thereby, connection layer 11 sufficiently has a function as a stress relaxation layer between single crystal substrates 1 to 9 and support substrate 10. The stress relaxation can reduce warpage of silicon carbide substrate 100. The porosity can be measured with, for example, an ultrasonic microscope. A method for adjusting the porosity will be described in Embodiment 2.

Further, support substrate 10 is preferably made of silicon carbide. In this case, since all of single crystal substrates 1 to 9, support substrate 10, and connection layer 11 at least have silicon carbide as a main component, the thermal expansion coefficient of support substrate 10 is also close to the thermal expansion coefficient of single crystal substrates 1 to 9, in addition to the thermal expansion coefficient of connection layer 11. Thereby, adhesion strength between connection layer 11 and support substrate 10 is also enhanced, and as a result, silicon carbide substrate 100 with a higher strength is obtained.

Further, connection layer 11 preferably has a crystallization degree lower than that of support substrate 10. In this case, connection layer 11 lies between single crystal substrates 1 to 9 each made of a single crystal having a crystallization degree higher than that of connection layer 11 and support substrate 10 having a crystallization degree higher than that of connection layer 11. Namely, connection layer 11 lies between single crystal substrates 1 to 9 having a Young's modulus higher than that of connection layer 11 and support substrate 10 having a Young's modulus higher than that of connection layer 11. Thus, connection layer 11 can have an enhanced function of relaxing stress. With silicon carbide substrate 100 as described above, damage, delamination, and the like due to stress applied to single crystal substrates 1 to 9 and/or support substrate 10 can be suppressed, and thus silicon carbide substrate 100 can have a further higher strength.

It is noted that, since connection layer 11 is formed by converting polycarbosilane as described above, connection layer 11 can be easily formed as a compound made of at least one of polycrystalline silicon carbide and amorphous silicon carbide, by appropriately adjusting a heating temperature at which polycarbosilane is converted, and a structure of polycarbosilane used.

Further, silicon carbide substrate 100 preferably has a diameter of not less than 110 mm. That is, surface 100a formed of the first front-side surfaces of single crystal substrates 1 to 9 preferably has a diameter of not less than 110 mm. By manufacturing a semiconductor device using such a large-diameter silicon carbide substrate, the semiconductor device can be manufactured more efficiently, and thus manufacturing cost can be reduced.

Further, silicon carbide substrate 100 preferably has a warpage of not more than 30 μm. By manufacturing a semiconductor device using such silicon carbide substrate 100, a high-quality semiconductor device can be easily manufactured.

Here, the “warpage” refers to a value indicating a degree of curvature of surface 100a formed of the first front-side surfaces of single crystal substrates 1 to 9. Specifically, a warpage of a surface of a substrate refers to a difference in height between the highest point and the lowest point in the surface in a case where the least squares plane of the surface has a reference height. It is noted that, although a concave portion due to a gap caused between single crystal substrates 1 to 9 may exist in surface 100a, the concave portion is not taken into consideration in the calculation of the “warpage” herein.

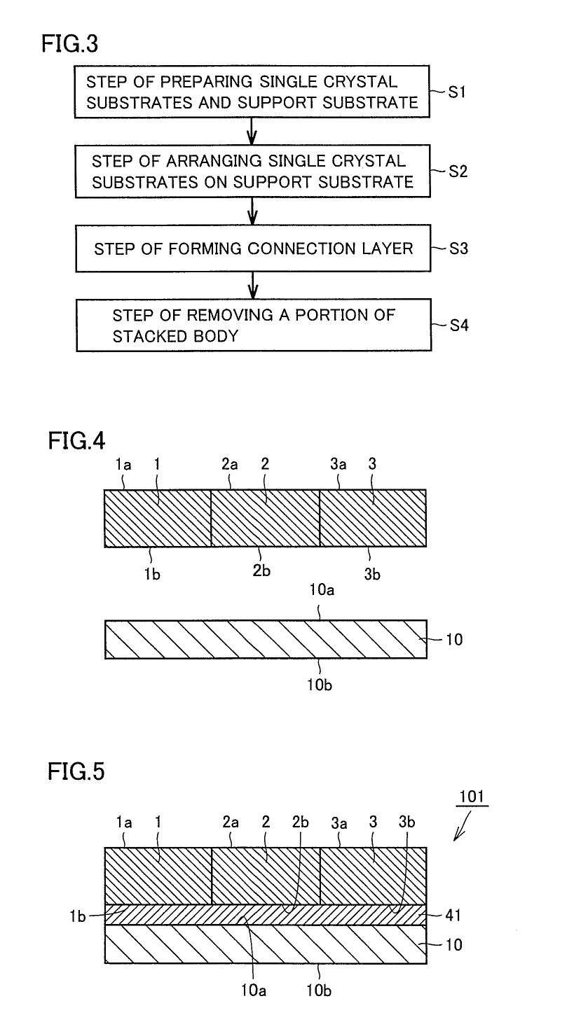

Next, a method for manufacturing silicon carbide substrate 100 in accordance with the present embodiment will be described with reference to FIGS. 1 to 5. FIG. 3 is a schematic flowchart of a method for manufacturing the silicon carbide substrate in accordance with Embodiment 1, and FIGS. 4 and 5 are cross sectional views each schematically showing one step of the method for manufacturing the silicon carbide substrate in accordance with Embodiment 1.

First, as shown in FIG. 4, a plurality of single crystal substrates 1 to 9 and support substrate 10 are prepared (FIG. 3: step S1).

As described above, each of the first front-side surfaces of single crystal substrates 1 to 9 preferably has a plane orientation which is off from the {0001} plane by not less than 0.1° and not more than 10°. Such single crystal substrates 1 to 9 can be prepared, for example, by slicing a silicon carbide ingot grown on a (0001) plane in a hexagonal system and adjusting its diameter by cutting, polishing, and the like. In addition, as described above, the first front-side surfaces of single crystal substrates 1 to 9 may each have a plane orientation which is off from the {03-38} plane by not more than 4°, or may each have a plane orientation which is off from the {01-12} plane or the {01-11} plane by not more than 4°.

Support substrate 10 is made of silicon carbide, carbon, ceramics, or a high-melting-point metal. In particular, from the viewpoint of obtaining support substrate 10 having physical properties closer to those of single crystal substrates 1 to 9, support substrate 10 is preferably made of silicon carbide. Specifically, a substrate made of polycrystalline silicon carbide, amorphous silicon carbide, or a mixture thereof can be suitably used. Further, low-quality single crystal silicon carbide having many dislocations, stacking faults, and the like can also be used.

Furthermore, from the viewpoint of manufacturing a silicon carbide substrate with a diameter of not less than 110 mm, it is preferable to select the sizes of single crystal substrates 1 to 9 and support substrate 10 such that, when the first front-side surfaces of the plurality of single crystal substrates 1 to 9 are arranged as shown in FIG. 1, surface 100a formed of the first front-side surfaces has a diameter of not less than 110 mm.

Next, as shown in FIG. 5, each of single crystal substrates 1 to 3 is arranged on support substrate 10 with a fluid layer 41 containing polycarbosilane interposed therebetween, such that each of first backside surfaces 1b to 3b of single crystal substrates 1 to 3 faces second front-side surface 10a of support substrate 10 (FIG. 3: step S2).

On this occasion, single crystal substrates 4 to 9 (not shown in FIG. 5) are also arranged on fluid layer 41, as with single crystal substrates 1 to 3. Thus, a plan view of a stacked body including single crystal substrates 1 to 9, fluid layer 41, and support substrate 10 viewed from the side of the first front-side surfaces of single crystal substrates 1 to 9 has the same configuration as that in FIG. 1. Thereby, a stacked body 101 including single crystal substrates 1 to 9, fluid layer 41, and support substrate 10 is fabricated. Specifically, stacked body 101 is fabricated as described below.

First, a fluid containing polycarbosilane is applied or sprayed onto second front-side surface 10a of support substrate 10 to form fluid layer 41 containing polycarbosilane on second front-side surface 10a. Fluid layer 41 may also be formed by heating and melting solid polycarbosilane. Next, first backside surfaces 1b to 3b of single crystal substrates 1 to 3 are arranged on fluid layer 41. Alternatively, fluid layer 41 may be formed on each of first backside surfaces 1b to 3b of single crystal substrates 1 to 3, and then second front-side surface 10a of support substrate 10 may be arranged on fluid layer 41.

It is noted that, in order to form connection layer 11 with a uniform thickness in the step of forming connection layer 11 (see FIG. 2) described later, it is preferable to form fluid layer 41 with a uniform thickness between support substrate 10 and single crystal substrates 1 to 3.

As described above, polycarbosilane contained in fluid layer 41 is a polymer having a Si—C bond in a main chain, and its number average molecular weight is preferably 600 to 4000. In addition, the fluid containing polycarbosilane may be prepared by dispersing or dissolving polycarbosilane in a solvent. If polycarbosilane itself is a fluid, the fluid containing polycarbosilane may be polycarbosilane itself. As the solvent, a low-polarity organic solvent such as xylene, hexane, or toluene can be suitably used.

Here, polycarbosilane may have, in the main chain, a silicon-silicon bond (hereinafter also referred to as a “Si—Si bond”) or a carbon-carbon bond (hereinafter also referred to as a “C—C bond”), other than the Si—C bond. For example, as one example of polycarbosilane, the main chain of polycarbosilane may have a repeating unit represented by chemical formula (1) described below, or may have respective repeating units represented by chemical formulas (2) and (3) described below. Further, the main chain may have a repeating unit represented by a combination of chemical formulas (1) to (3) described below. However, in order to say that connection layer 11 formed by converting polycarbosilane is made of a compound having silicon carbide as a main component, preferably not less than 50% of the atoms constituting the main chain form Si—C bonds. More preferably, not less than 70% thereof form Si—C bonds, and further preferably, not less than 90% thereof form Si—C bonds.

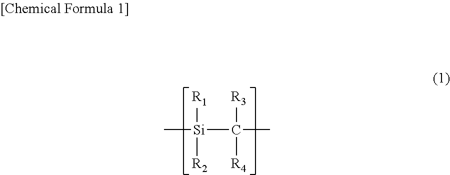

In chemical formula (1), R₁ to R₄ each represent a hydrogen group, or an alkyl group, an alkenyl group, or an alkynyl group having a carbon number of 1 to 5, and they may be different from each other. In addition, R₁ to R₄ included in the structure of the repeating unit may be identical to or different from each other.

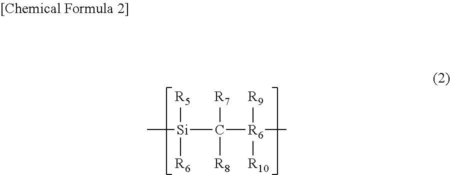

In chemical formula (2), R₅ to R₁₀ each represent a hydrogen group, or an alkyl group, an alkenyl group, or an alkynyl group having a carbon number of 1 to 5, and they may be different from each other. In addition, R₅ to R₁₀ included in the structure of the repeating unit may be identical to or different from each other.

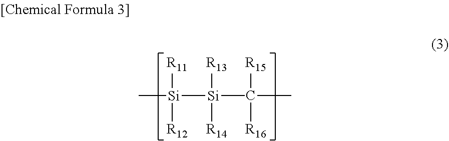

In chemical formula (3), R₁₁ to R₁₆ each represent a hydrogen group, or an alkyl group, an alkenyl group, or an alkynyl group having a carbon number of 1 to 5, and they may be different from each other. In addition, a plurality of R₁₁ to R₁₆ included in the structure of the main chain may be identical to or different from each other.

Further, in the step of forming the connection layer described later, polycarbosilane contained in fluid layer 41 is converted and transformed into connection layer 11 having silicon carbide as a main component. Since carbon in a side chain portion of polycarbosilane partially remains, ratio A/B between number A of carbon atoms and number B of silicon atoms in connection layer 11 becomes not less than 1 and not more than 2.

Next, as shown in FIG. 2, connection layer 11 having silicon carbide as a main component is formed by converting polycarbosilane contained in fluid layer 41 (FIG. 3: step S3).

For example, by subjecting fluid layer 41 to heating treatment under an inert atmosphere, polycarbosilane is converted, and the solvent is volatilized and removed. Thereby, fluid layer 41 is converted into connection layer 11 having silicon carbide as a main component.

In the heating treatment, it is preferable to heat fluid layer 41 at not less than 1000° C. and not more than 2000° C. By heating fluid layer 41 in this temperature range, conversion ratio of polycarbosilane into a compound having silicon carbide as a main component can be improved, while suppressing an increase in dislocation density in single crystal substrates 1 to 9. Further, the heating can also suppress sublimation of the front-side surfaces of single crystal substrates 1 to 9 and resultant shape deformation. It is noted that, when fluid layer 41 is subjected to heating treatment at not less than 1900° C., it is preferable to set a pressure in the atmosphere during the heating treatment to not less than 4×10⁴ Pa, in order to suppress an increase in dislocation density in single crystal substrates 1 to 9 and also suppress deformation of single crystal substrates 1 to 9.

Furthermore, by heating fluid layer 41 at not less than 1000° C. and not more than 1800° C., the increase in dislocation density can be further suppressed. In addition, warpage of silicon carbide substrate 100 due to conversion of polycarbosilane can be suppressed, for the reason described below.

When polycarbosilane is converted into a compound having silicon carbide as a main component, hydrogen atoms, carbon atoms, and the like are desorbed from the polymer constituting polycarbosilane. Polycarbosilane is finally solidified into a compound having silicon carbide as a main component that has a Si—C bond, a C—C bond, a Si—Si bond, and the like, and thereby solid connection layer 11 is formed. If the heating temperature is high on this occasion, excessive desorption of hydrogen atoms, carbon atoms, and the like is caused, and thus contraction of connection layer 11 may be promoted, and the volume of formed connection layer 11 may become excessively smaller than the volume of fluid layer 41. If the volume of connection layer 11 becomes excessively smaller than the volume of fluid layer 41, warpage occurs in support substrate 10 or in surface 100a formed of first front-side surfaces 1a to 3a of single crystal substrates 1 to 3, and as a result, a large warpage occurs in silicon carbide substrate 100.

In contrast, if fluid layer 41 is heated at not less than 1000° C. and not more than 1800° C., since the heating is performed under a relatively low-temperature environment, the increase in dislocation density in single crystal substrates 1 to 9 can be suppressed, and warpage of silicon carbide substrate 100 can be suppressed.

Further, fluid layer 41 is preferably heated at not less than 1500° C. Thereby, binding reaction between polycarbosilane and each of single crystal substrates 1 to 9 is promoted, and binding reaction between polycarbosilane and support substrate 10 is promoted. Furthermore, crystallization in connection layer 11 further proceeds. Therefore, strength of connection by connection layer 11 can be increased.

In addition, it is preferable in the heating treatment to gradually increase the heating temperature from about room temperature (25° C.) to the temperature range described above. Since this can further suppress contraction of fluid layer 41, occurrence of warpage in silicon carbide substrate 100 can be suppressed more efficiently. Further, by controlling the rate of temperature increase, hydrogen atoms and carbon atoms in polycarbosilane can be efficiently desorbed.

Through the steps described above, silicon carbide substrate 100 can be fabricated. According to the present embodiment, warpage of silicon carbide substrate 100 can be suppressed to, for example, not more than 50 μm, by adjusting selection of polycarbosilane, conditions for heating fluid layer 41, and the like as described above.

If a large-diameter semiconductor substrate for efficiently manufacturing a semiconductor device has a small warpage of, for example, not more than 30 μm, high-quality semiconductor devices can be manufactured with high yield. Thus, if silicon carbide substrate 100 has a warpage of more than 30 μm, it is preferable to further perform the step of removing a portion of silicon carbide substrate 100 (FIG. 3: step S4).

As a method for improving flatness of silicon carbide substrate 100 by removing a portion of silicon carbide substrate 100, it is preferable to use a method for polishing surface 100a formed of single crystal substrates 1 to 3 constituting silicon carbide substrate 100. Thereby, warpage of silicon carbide substrate 100 can be easily reduced to not more than 30 μm. As the polishing, multistep polishing such as lapping and finish-polishing can be performed. Further, from the viewpoint of suppressing surface roughness of surface 100a, it is preferable to finish the surface by CMP (Chemical Mechanical Polishing).

With the present step, even if silicon carbide substrate 100 after step S3 has a warpage of more than 30 μm, the warpage of silicon carbide substrate 100 can be easily reduced to not more than 30 μm. Thereby, silicon carbide substrate 100 more suitable as a semiconductor substrate for manufacturing a semiconductor device can be fabricated.

In addition, since silicon carbide substrate 100 immediately after connection layer 11 is formed has a warpage of not more than 50 μm as described above, silicon carbide substrate 100 before being subjected to the present step has flatness higher than that of a conventional substrate. Therefore, processing cost and processing time required for processing treatment in the present step can be reduced, when compared with those in a conventional case. Further, warpage after the present step can be reduced.

The silicon carbide substrate in accordance with Embodiment 1 and the method for manufacturing the same have been described in detail with reference to FIGS. 1 to 5. The silicon carbide substrate has characteristics significantly different from those of a silicon carbide substrate fabricated by a conventional close-spaced sublimation method. Detailed description will be given below in this regard.

Unlike the present embodiment, in a case where a plurality of single crystal substrates are integrated by the close-spaced sublimation method, the single crystal substrates are exposed to a high-temperature environment at about the sublimation temperature of SiC, and dislocation defects tend to be generated in the SiC single crystal substrates, in particular on an interface side thereof.

The inventor of the present invention has found that, when single crystal substrates having dislocation densities of, for example, 9000 dislocations/cm², 25000 dislocations/cm², 35000 dislocations/cm², and 50000 dislocations/cm² were used, the dislocation densities of the single crystal substrates on the interface side after being subjected to the close-spaced sublimation method tended to be increased to 330000 dislocations/cm², 370000 dislocations/cm², 410000 dislocations/cm², and 480000 dislocations/cm², respectively.

In contrast, according to the present invention, the single crystal substrates and the support substrate can be connected by converting polycarbosilane contained in the fluid layer into the connection layer having silicon carbide as a main component, without using the close-spaced sublimation method. Since conversion of polycarbosilane can be performed by heating treatment at not more than 2000° C., more preferably not more than 1900° C., and further preferably not more than 1800° C., the temperature to which the single crystal substrates are exposed can be suppressed, when compared with the case where the close-spaced sublimation method is used. Thus, an increase in dislocation density can be suppressed. When the present method was performed using single crystal substrates having dislocation densities of, for example, 25000 dislocations/cm² and 35000 dislocations/cm², the dislocation densities of the single crystal substrates on the interface side after being subjected to the present method were 25000 dislocations/cm² and 35000 dislocations/cm², respectively, which were identical to the values obtained before being subjected to the present method.

### Embodiment 2

The present embodiment is different from Embodiment 1 in that connection layer 11 contains a filler 71 made of silicon carbide. Hereinafter, the difference from Embodiment 1 will be described.

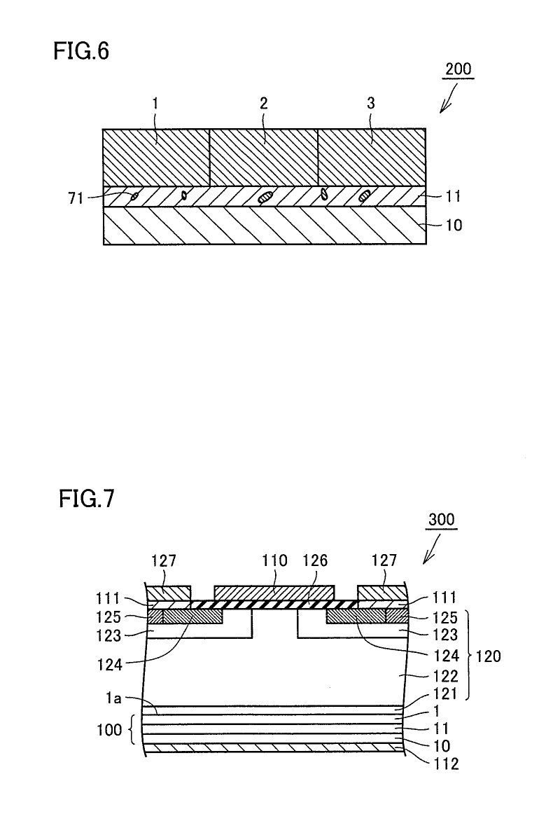

FIG. 6 is a cross sectional view schematically showing a structure of a silicon carbide substrate in accordance with Embodiment 2 of the present invention. Referring to FIG. 6, connection layer 11 contains filler 71 made of silicon carbide. This can suppress volume contraction when polycarbosilane is converted and transformed from fluid layer 41 to connection layer 11.

For example, polycrystalline silicon carbide can be used as filler 71. Preferably, the content per volume of filler 71 in fluid layer 41 is not less than 10 volume % and not more than 70 volume %. By setting the content per volume of filler 71 to not less than 10 volume %, contraction can be sufficiently suppressed, and by setting the content per volume of filler 71 to not more than 70 volume %, strength of connection layer 11 can be maintained. More preferably, the content per volume of filler 71 is not less than 20 volume % and not more than 60 volume %. Connection layer 11 containing filler 71 described above can be formed, for example, by a method described below.

Specifically, in step S2 described above, filler 71 is further contained in fluid layer 41 containing polycarbosilane, and each of single crystal substrates 1 to 3 is arranged on support substrate 10 with fluid layer 41 interposed therebetween to fabricate a stacked body. Then, through the same step as that in Embodiment 1 (i.e., step S3, or steps S3 and S4), a silicon carbide substrate 200 having connection layer 11 shown in FIG. 6 can be fabricated.

The size of filler 71 is preferably not more than 10 μm, more preferably not more than 5 μm, more preferably not more than 3 μm, and more preferably not more than 1 μm. If the size of filler 71 is too large, each of single crystal substrates 1 to 9 cannot fully come close to support substrate 10, leading to a reduction in adhesion strength.

Further, using filler 71 causes a reduction in the porosity of connection layer 11. Thus, the porosity of connection layer 11 can be adjusted by adjusting the amount of filler 71 contained in fluid layer 41. The porosity of connection layer 11 can also be adjusted by a technique other than adjustment of the amount of filler 71. For example, the porosity can be reduced by containing dispersed silicon (Si) in the fluid forming fluid layer 41 (FIG. 5). Since polycarbosilane has a molecular structure having excess C atoms, C atoms become excessive during decomposition by heating. The excessive C atoms exist in a gap in connection layer 11. When silicon is added to the fluid as described above, Si atoms in the dispersed silicon react with the excessive C atoms and generate SiC. The gap is filled due to the generation of SiC, and thus the porosity is reduced. Preferably, silicon is added so as not to exceed an amount effective for the generation of SiC.

The porosity can also be adjusted based on the magnitude of pressurization during heating of fluid layer 41. The porosity can be decreased by increasing pressure of pressurization, and can be increased by decreasing pressure of pressurization.

Further, the porosity can also be adjusted based on the amount of polycarbosilane in the fluid. The porosity can be decreased by increasing the amount, and can be increased by decreasing the amount.

### Embodiment 3

Referring to FIG. 7, a semiconductor device 300 (silicon carbide semiconductor device) in accordance with Embodiment 3 is a vertical DiMOSFET (Double Implanted Metal Oxide Semiconductor Field Effect Transistor), having silicon carbide substrate 100, an oxide film 126, a source electrode 111, an upper source electrode 127, a gate electrode 110, a drain electrode 112, and an epitaxial layer 120. Epitaxial layer 120 has a buffer layer 121, a breakdown voltage holding layer 122, a p region 123, an n⁺ region 124, and a p⁺ region 125.

In the present embodiment, silicon carbide substrate 100 has n-type conductivity, and has support substrate 10, connection layer 11, and single crystal substrate 1. Drain electrode 112 is provided on support substrate 10 of silicon carbide substrate 100. Buffer layer 121 is provided on single crystal substrate 1 of silicon carbide substrate 100.

Buffer layer 121 has n-type conductivity, and its thickness is, for example, 0.5 μm. The concentration of an n-type conductive impurity in buffer layer 121 is, for example, 5×10¹⁷ cm⁻³.

Breakdown voltage holding layer 122 is formed on buffer layer 121, and it is made of silicon carbide having n-type conductivity. For example, the thickness of breakdown voltage holding layer 122 is 10 μm, and the concentration of its n-type conductive impurity is 5×10¹⁵ cm⁻³.

On a front-side surface of breakdown voltage holding layer 122, a plurality of p regions 123 having p-type conductivity are formed to be spaced apart from each other. Inside p region 123, n⁺ region 124 is formed at a surface layer of p region 123. In addition, p⁺ region 125 is formed at a position next to n⁺ region 124. Oxide film 126 is formed to extend on n⁺ region 124 in one p region 123, one p region 123, breakdown voltage holding layer 122 exposed between two p regions 123, the other p region 123, and n⁺ region 124 in the other p region 123. On oxide film 126, gate electrode 110 is formed. Further, on n⁺ region 124 and p⁺ region 125, source electrode 111 is formed. On source electrode 111, upper source electrode 127 is formed.

In a region within 10 nm from an interface between oxide film 126 and n⁺ regions 124, p⁺ regions 125, p regions 123, and breakdown voltage holding layer 122 each of which serves as a semiconductor layer, the concentration of nitrogen atoms has a maximum value of not less than 1×10²¹ cm⁻³. Thereby, mobility particularly at a channel region below oxide film 126 (i.e., a portion of p region 123 in contact with oxide film 126 between n⁺ region 124 and breakdown voltage holding layer 122) can be improved.

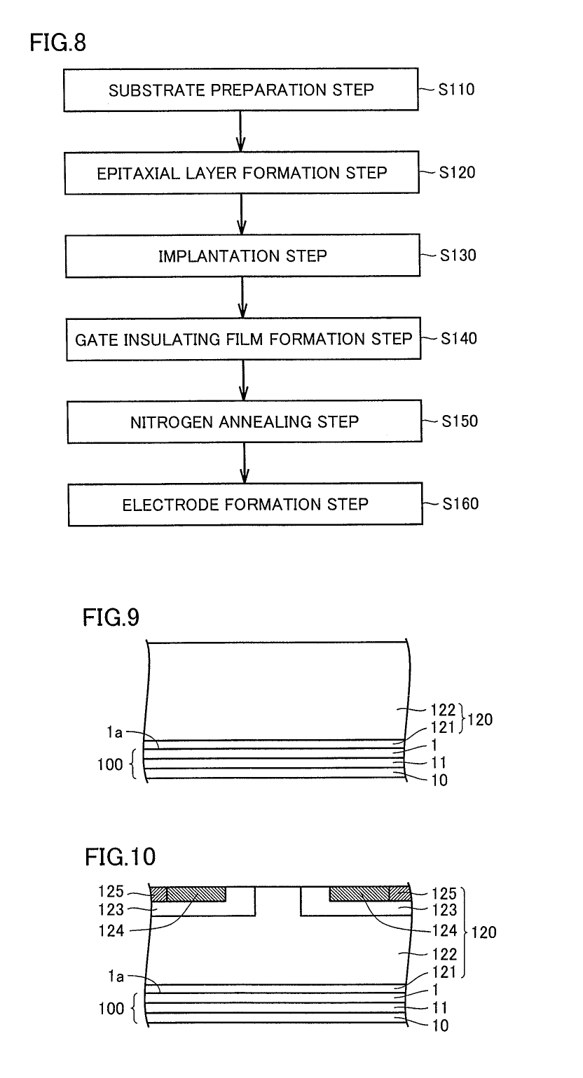

Next, a method for manufacturing semiconductor device 300 will be described with reference to FIGS. 7 to 12. FIG. 8 is a schematic flowchart of a method for manufacturing the semiconductor device in accordance with Embodiment 3, and FIGS. 9 to 12 are cross sectional views each schematically showing one step of the method for manufacturing the semiconductor device in accordance with Embodiment 3. Although FIGS. 9 to 12 only show the steps in the vicinity of single crystal substrate 1 among single crystal substrates 1 to 9 (see FIG. 1), the same steps are also performed in the vicinity of each of single crystal substrates 2 to 9.

First, in a substrate preparation step (step S110) in FIG. 8, silicon carbide substrate 100 is prepared (see FIGS. 1 and 2). Specifically, silicon carbide substrate 100 is fabricated through steps S1 to S3 or steps S1 to S4 described above. It is noted that, in the present embodiment, silicon carbide substrate 100 can have n-type conductivity, for example, by introducing an n-type impurity such as nitrogen or phosphorus into silicon carbide constituting single crystal substrates 1 to 9, support substrate 10, and connection layer 11.

Next, in an epitaxial layer formation step (step S120) in FIG. 8, epitaxial layer 120 including buffer layer 121 and breakdown voltage holding layer 122 is formed in the following manner (see FIG. 9).

First, on a front-side surface of silicon carbide substrate 100, buffer layer 121 is formed. Buffer layer 121 is made of silicon carbide having n-type conductivity, and, by way of example, it is an epitaxial layer of 0.5 μm in thickness. Further, the concentration of the conductive impurity in buffer layer 121 is, for example, 5×10¹⁷ cm⁻³.

Next, breakdown voltage holding layer 122 is formed on buffer layer 121. Specifically, a layer made of silicon carbide having n-type conductivity is formed by epitaxial growth. The thickness of breakdown voltage holding layer 122 is, for example, 10 μm. The concentration of the n-type conductive impurity in breakdown voltage holding layer 122 is, for example, 5×10¹⁵ cm⁻³.

Subsequently, in an implantation step (step S130) in FIG. 8, p region 123, n⁺ region 124, and p⁺ region 125 are formed in the following manner (see FIG. 10).

First, an impurity having p-type conductivity is selectively implanted into a portion of breakdown voltage holding layer 122 to form p region 123. Next, an n-type conductive impurity is selectively implanted into a predetermined region to form n⁺ region 124, and a p-type conductive impurity is selectively implanted into a predetermined region to form p⁺ region 125. Selective implantation of the impurities is performed using a mask made of, for example, an oxide film. After such an implantation step, activation annealing treatment is performed. For example, the annealing is performed in an argon atmosphere at a heating temperature of 1700° C. for 30 minutes.

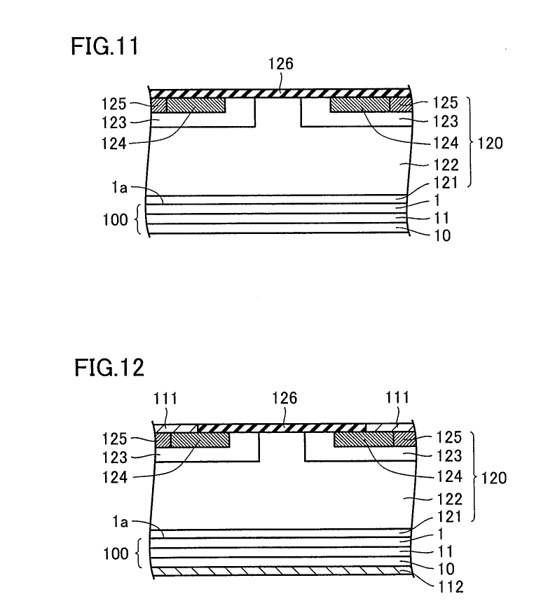

Next, in a gate insulating film formation step (step S140) in FIG. 8, oxide film 126 as a gate insulating film is formed (see FIG. 11).

Specifically, oxide film 126 is formed to cover breakdown voltage holding layer 122, p regions 123, n⁺ regions 124, and p⁺ regions 125. The film may be formed by dry oxidation (thermal oxidation). Conditions for the dry oxidation are, for example, heating temperature of 1200° C. and heating time of 30 minutes.

Subsequently, in a nitrogen annealing step (step S150) in FIG. 8, annealing treatment is performed.

Specifically, annealing treatment is performed in a nitrogen monoxide (NO) atmosphere. Conditions for this treatment are, for example, heating temperature of 1100° C. and heating time of 120 minutes. As a result, nitrogen atoms are introduced into the vicinity of the interface between oxide film 126 and each of breakdown voltage holding layer 122, p regions 123, n⁺ regions 124, and p⁺ regions 125. It is noted that, after the annealing step using nitrogen monoxide, annealing treatment using argon (Ar) gas as an inert gas may be further performed. Conditions for this treatment are, for example, heating temperature of 1100° C. and heating time of 60 minutes.

Next, in an electrode formation step (step S160) in FIG. 8, source electrode 111 and drain electrode 112 are formed in the following manner (see FIG. 12). First, on oxide film 126, a resist film having a pattern is formed using photolithography. Using the resist film as a mask, portions of oxide film 126 positioned on n⁺ regions 124 and p⁺ regions 125 are removed by etching. Thus, openings are formed in oxide film 126. Next, a conductive film is formed to be in contact with each of n⁺ regions 124 and p⁺ regions 125 in each of the openings. Then, the resist film is removed, and thereby portions of the conductive film that have been positioned on the resist film are removed (lift off). The conductive film may be a metal film, and, by way of example, it is made of nickel (Ni). As a result of this lift off, source electrode 111 is formed on epitaxial layer 120. Here, heat treatment for alloying is preferably performed. By way of example, the heat treatment is performed in an atmosphere of argon (Ar) gas as an inert gas, at a heating temperature of 950° C. for 2 minutes.

Furthermore, upper source electrode 127 is formed on source electrode 111, and drain electrode 112 is formed on a backside surface of silicon carbide substrate 100 (see FIG. 7). Then, the stacked body is diced into individual semiconductor devices. Thereby, semiconductor device 300 including silicon carbide substrate 100 having first front-side surface 1a of single crystal substrate 1 is obtained.

In addition, after upper source electrode 127 is formed on source electrode 111, support substrate 10 and connection layer 11 can be removed by grinding the backside surface to leave single crystal substrate 1 only, and drain electrode 112 may be formed on a backside surface of single crystal substrate 1. For example, in a case where high-resistance support substrate 10 is used, the resistance of the semiconductor device can be reduced by removing support substrate 10 as described above. Further, the thickness of single crystal substrate 1 can also be reduced by grinding the backside surface. The resistance of the semiconductor device can be further reduced by reducing the thickness of single crystal substrate 1.

It is noted that a configuration in which conductivity types are opposite to those in the present embodiment, that is, a configuration with p-type and n-type reversed, can also be used.

Further, a semiconductor substrate for fabricating semiconductor device 300 is not limited to silicon carbide substrate 100 in accordance with Embodiment 1, and, for example, may be silicon carbide substrate 200 obtained by Embodiment 2.

Furthermore, although a vertical DiMOSFET has been described as an example in the present embodiment, other semiconductor devices may be manufactured using the silicon carbide substrate in accordance with the present invention. For instance, a RESURF-JFET (Reduced Surface Field-Junction Field Effect Transistor) or a Schottky diode may be manufactured.

According to the method for manufacturing a semiconductor device in accordance with the present embodiment, a silicon carbide substrate which has a high connection strength and is less likely to be delaminated, and also has a high strength can be used as a semiconductor substrate. Thus, the semiconductor device can have a high strength. Further, when compared with a silicon carbide substrate fabricated by the conventional close-spaced sublimation method, occurrence of dislocation defects as well as occurrence of voids in the support substrate are suppressed in the silicon carbide substrate in accordance with the present embodiment. Accordingly, a high-quality semiconductor device can be obtained as a result.

Furthermore, since a plurality of semiconductor devices can be efficiently manufactured using a high-quality and large-diameter silicon carbide substrate, manufacturing cost of the semiconductor devices can be reduced. In addition, since the silicon carbide substrate has a small warpage, yield of the semiconductor devices can be improved.

### Examples

Silicon carbide substrates 100 having various porosities were fabricated as samples 1 to 9 by a method for adjusting porosity described above. Then, warpage of each silicon carbide substrate 100 and breakage yield when silicon carbide semiconductor devices were manufactured using the same were investigated. Here, the “breakage yield” refers to a probability of non-occurrence of a failure due to breakage of silicon carbide substrate 100 in the manufacturing of the silicon carbide semiconductor devices using silicon carbide substrate 100. Table 1 below shows results.

TABLE 1

| Samples | 1 | 2 | 3 | 4 | 5 | 6 | 7 | 8 | 9 |
|---|---|---|---|---|---|---|---|---|---|
| Porosity (%) | 2 | 3 | 5 | 10 | 20 | 40 | 50 | 65 | 75 |
| Warpage (μm) | 39 | 28 | 16 | 11 | 5 | 8 | 12 | 18 | 22 |
| Breakage Yield (%) | 78 | 92 | 93 | 91 | 88 | 76 | 66 | 54 | 27 |

As is clear from the results, silicon carbide substrates 100 having porosities of not less than 3% and not more than 75% had warpages smaller than that of silicon carbide substrate 100 having a porosity of 2%. Further, silicon carbide substrates 100 having porosities of not less than 2% and not more than 65% had breakage yields higher than that of silicon carbide substrate 100 having a porosity of 75%. Thus, it was found that the porosity of not less than 3% and not more than 65% is particularly preferable as conditions for achieving a small warpage and a high breakage yield.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide substrate, comprising:
a plurality of single crystal substrates made of silicon carbide and each having a first front-side surface and a first backside surface opposite to each other;
a support substrate having a second front-side surface and a second backside surface opposite to each other; and
a connection layer having silicon carbide as a main component and lying between said plurality of single crystal substrates and said support substrate for connecting each of said first backside surfaces and said second front-side surface such that each of said first backside surfaces faces said second front-side surface.

2. The silicon carbide substrate according to claim 1, wherein said connection layer has a porosity of not less than 3% and not more than 65%.

3. The silicon carbide substrate according to claim 1, wherein said support substrate is made of silicon carbide.

4. The silicon carbide substrate according to claim 3, wherein said connection layer has a crystallization degree lower than that of said support substrate.

5. The silicon carbide substrate according to claim 1, wherein said connection layer has at least one of polycrystalline silicon carbide and amorphous silicon carbide as a main component.

6. The silicon carbide substrate according to claim 1, wherein a ratio A/B between a number A of carbon atoms and a number B of silicon atoms in said connection layer is not less than 1 and not more than 2.

7. The silicon carbide substrate according to claim 1, wherein the silicon carbide substrate has a diameter of not less than 110 mm.

8. The silicon carbide substrate according to claim 1, wherein the silicon carbide substrate has a warpage of not more than 30 μm.

9. The silicon carbide substrate according to claim 1, wherein each of said plurality of single crystal substrates has a hexagonal crystal structure, and said first front-side surface has a plane orientation which is off from a {0001} plane by not less than 0.1° and not more than 10°.

10. The silicon carbide substrate according to claim 1, wherein each of said plurality of single crystal substrates has a hexagonal crystal structure, and said first front-side surface has a plane orientation which is off from a {03-38} plane by not more than 4°.

11. A silicon carbide semiconductor device, comprising:
a single crystal substrate made of silicon carbide and having a first front-side surface and a first backside surface opposite to each other;
a support substrate having a second front-side surface and a second backside surface opposite to each other;
a connection layer having silicon carbide as a main component and lying between said single crystal substrate and said support substrate for connecting said first backside surface and said second front-side surface such that said first backside surface faces said second front-side surface;
an epitaxial layer provided on said first front-side surface of said single crystal substrate and made of silicon carbide; and
an electrode provided on said epitaxial layer.

12. A method for manufacturing a silicon carbide substrate, comprising the steps of:
preparing a plurality of single crystal substrates and a support substrate, said plurality of single crystal substrates being made of silicon carbide and each having a first front-side surface and a first backside surface opposite to each other, said support substrate having a second front-side surface and a second backside surface opposite to each other;
arranging each of said plurality of single crystal substrates on said support substrate with a fluid layer containing polycarbosilane interposed therebetween, such that each of said first backside surfaces of said plurality of single crystal substrates faces said second front-side surface of said support substrate; and
forming a connection layer having silicon carbide as a main component by converting said polycarbosilane.

13. The method for manufacturing a silicon carbide substrate according to claim 12, wherein said fluid layer contains dispersed silicon.

14. The method for manufacturing a silicon carbide substrate according to claim 12, wherein the step of forming said connection layer includes the step of heating said fluid layer at not less than 1000° C. and not more than 2000° C.

15. The method for manufacturing a silicon carbide substrate according to claim 12, wherein said fluid layer contains a filler made of silicon carbide.

16. The method for manufacturing a silicon carbide substrate according to claim 12, wherein, after the step of forming said connection layer, said silicon carbide substrate has a warpage of not more than 50 μm.

17. A method for manufacturing a silicon carbide semiconductor device, comprising the steps of:
preparing a silicon carbide substrate including a single crystal substrate, a support substrate, and a connection layer, said single crystal substrate being made of silicon carbide and having a first front-side surface and a first backside surface opposite to each other, said support substrate having a second front-side surface and a second backside surface opposite to each other, said connection layer having silicon carbide as a main component and lying between said single crystal substrate and said support substrate for connecting said first backside surface and said second front-side surface such that said first backside surface faces said second front-side surface;
forming an epitaxial layer on said single crystal substrate; and
forming an electrode on said epitaxial layer.
